(19) United States
(12) Patent Application Publication
(10) Pub. No.: US 2008/0079129 A1
(43) Pub. Date: Apr. 3, 2008

(54) Shape memory based mechanical enabling mechanism

(76) Inventors: Shankar Ganapathysubramanian, Phoenix, AZ (US); Sandeep Sane, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/540,045

(22) Filed: Sep. 29, 2006

(51) Int. Cl. H01L 21/00

(52) U.S. Cl. 257/678; 438/106

(57) ABSTRACT

Semiconductor packages and methods to fabricate thereof are described. A decoupling assembly is disposed between a package substrate and a circuit board. The decoupling assembly engages in response to a stimulus such that a semiconductor die is de-coupled from a socket and a circuit board. The decoupling assembly engages in response to a stimulus such that a semiconductor die is decoupled from a substrate. A decoupling assembly includes a clamping device, springs, and shape memory alloy rods. The shape memory alloy rods are actuators that generate motion or a pre-programmed shape to apply force when thermally excited. When the thermal excitation or other stimulus is removed, the shape memory alloy rods tend to return to their original shape, thus relieving any load or motion generated.

### FIELD

Embodiments of the invention relate generally to the field of semiconductor manufacturing, and more specifically, to semiconductor packages and methods to fabricate thereof.

### BACKGROUND

Semiconductor packages experience mechanical shock and vibration during operation. Typically, semiconductor packages are manufactured to withstand approximately 50 g of board level mechanical shock and 3.13 g of RMS board level random vibration. It is expected that semiconductor packages will require more power and significant increases in heat sink mass, generated by semiconductor packages while operating, will cause failure mechanisms such as processor pull-out and processor-socket solder joint failure.

Key driving factors for mechanical damage during maximum operating conditions typically arise from the level of heat sink mass generated and the quantity of surface mount components. Additionally, the current trend of using lead-free solders in semiconductor packages has significantly decreased shock performance relative to previous generation semiconductor packages.

### BRIEF DESCRIPTION OF THE DRAWINGS

The present invention is illustrated by way of example and not limitation in the figures of the accompanying drawings, in which like references indicate similar elements, and in which:

FIG. 1 shows a cross-section of a disengaged decoupling assembly coupled to a semiconductor package and a circuit board.

FIG. 2 shows a cross-section of an engaged decoupling assembly coupled to a semiconductor package and a circuit board.

FIG. 3 shows a cross-section of a semiconductor package featuring a semiconductor die disposed over a substrate, and an engaged decoupling assembly disposed on a substrate.

FIG. 4 shows a cross-section of a semiconductor package featuring a semiconductor die disposed over a substrate and a disengaged decoupling assembly disposed on a substrate.

FIG. 5 is an exploded view of a decoupling assembly featuring a clamping device, shape memory alloy rod, and a spring.

### DETAILED DESCRIPTION

A mechanical enabling solution for package substrates featuring a decoupling assembly is described. For an embodiment, a decoupling assembly is disposed between a semiconductor package and a circuit board. For the embodiment, a decoupling assembly engages in response to a stimulus (or stimuli) such that a semiconductor die is de-coupled from a socket and a circuit board. Under temperate conditions, however, the decoupling assembly is disengaged and a semiconductor die remains in a socket disposed on a circuit board. For other embodiments, a semiconductor package features a decoupling assembly. For these embodiments, the decoupling assembly engages in response to a stimulus (or stimuli) such that a semiconductor die is de-coupled from a package substrate. For an embodiment, a decoupling assembly includes a clamping device, springs, and shape memory alloy rods. For embodiments, shape memory alloy rods are actuators that may generate motion to a pre-programmed shape and/or apply force when thermally excited. Upon the condition that thermal excitation or other stimuli are removed, the shape memory alloy rods tend to return to their original shape, thus relieving a load or motion generated.

For embodiments, the mechanical enabling solution described improves microprocessor performance during periods of shock and vibration while also improving the performance of a thermal interface material (TIM). The performance of thermal interface materials (TIM) may be improved to reduce solder creep. In addition to performance improvements, significant form-factor and weight reduction can be achieved which further increases the number of applications to use high performance processors.

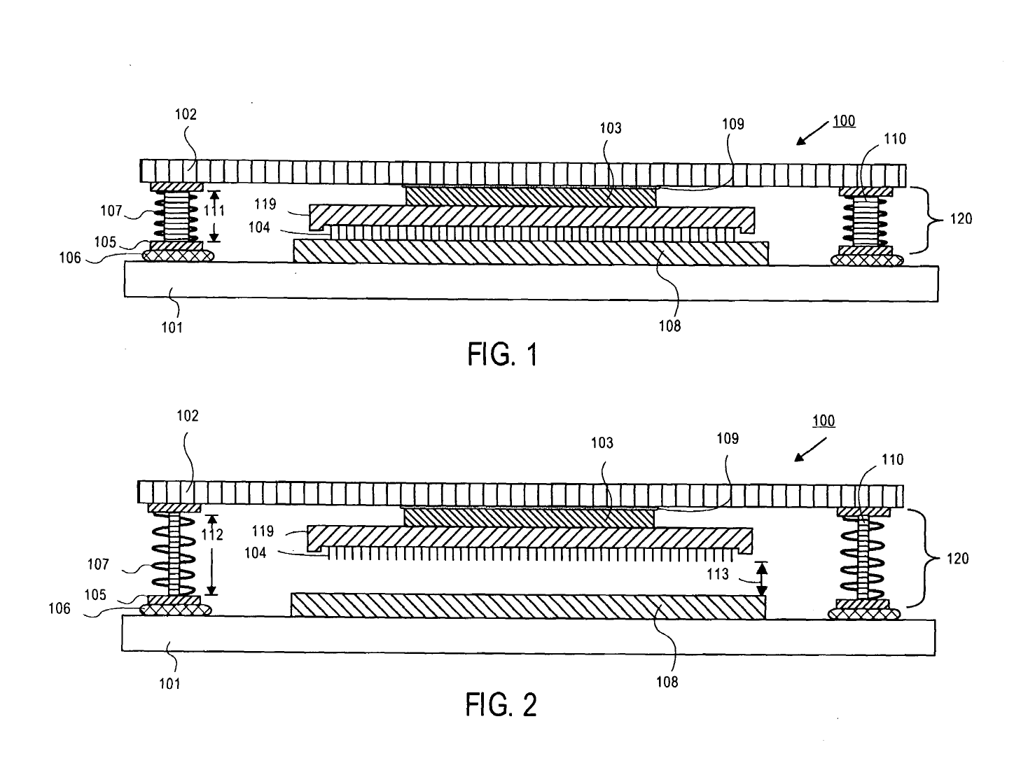

FIG. 1 is a cross-section of a semiconductor package 100 mounted to a circuit board 101. For the embodiment shown, a decoupling assembly 120 is disposed between circuit board 101 and an integrated heat spreader 102 to relieve a mechanical load induced upon semiconductor package 100 by enabling and/or non-enabling components. Enabling components are those that thermally or mechanically secure an electronic package. In an embodiment, screws, nuts, bolts and heatsinks are typical enabling components. Non-enabling components are components other than enabling components that enable electrical (rather than physical as screws, nuts, etc.) function of the electronic package, which do not function to thermally or mechanically secure an electronic package. The term “non-enabling component” also includes the electronic package itself. In an embodiment, voltage regulator boards, power connector, and electronic packages are typical non-enabling components.

As shown in FIG. 1, semiconductor package 100 features an integrated heat spreader 102 mounted to a semiconductor die 103 via a thermal interface material 109. FIG. 1 also shows package substrate 119 coupled to a socket 108 by pins 104. For an embodiment, package substrate 119 remains coupled to socket 108 while decoupling assembly 120 is disengaged. Additionally, two decoupling assemblies 120 are shown disposed between circuit board 101 and integrated heat spreader 102 via an adhesive, second thermal interface material 106. Decoupling assembly 120 features a spring 107, a clamping device 105, and an actuator 110. Actuator 110 maintains a length 111 defined as the length of actuator 110 during the condition that decoupling assembly 120 is disengaged.

Decoupling assembly 120 engages upon a threshold stimulus such as, but not limited to, thermal excitation, shock, or vibration. The aforementioned stimuli are typical conditions during the normal operation of a computing system and may be the source of multiple failure mechanisms therein. For an embodiment, decoupling assembly 120 engages in response to a thermal excitation stimulus that exceeds approximately 125° C. For another embodiment, decoupling assembly 120 engages in response to a shock stimulus that exceeds 50 G of board level mechanical shock. For other embodiments, decoupling assembly 120 engages in response to a vibration stimulus that exceeds 3.13 G RMS board level random vibration. Decoupling assembly 120 can engage in response to a combination of one or more of the aforementioned stimuli.

FIG. 2 shows a cross-section of a semiconductor package 100 mounted to a circuit board 101 when decoupling assembly 120 is engaged. As shown, decoupling assembly 120 separates package substrate 119 from socket 108 by a distance defined by gap 113. For embodiments, the separation distance of package substrate pins 104 and socket 108 can also define gap 113. During the condition that decoupling assembly is engaged, gap 113 can extend to approximately 2.0 mm and for an embodiment, gap 113 extends to approximately 0.2 mm. For the embodiment shown in FIG. 2, while decoupling assembly 120 is engaged, semiconductor package 100 is not coupled to circuit board 101 and therefore can not communicate therewith. Once decoupling assembly 120 is disengaged, package substrate 119 re-couples to socket 108 and semiconductor package 100 regains communication with circuit board 101.

Additionally, while decoupling assembly 120 is engaged, actuators 110 obtain a new length 112. For an embodiment, length 112 is greater than length 111 because the length of actuators 110 elongates when decoupling assembly 120 is engages and contracts when decoupling assembly disengages 120. Accordingly, when decoupling assembly 120 is engaged length 112 of actuators 110 may range from 0 to 2.0 mm longer than the length 111 of actuators 110 when decoupling assembly 120 is disengaged.

The width of actuators 110 can also change while decoupling assembly 120 cycles from an engaged to a disengaged state (and vice versa). For example, the width of actuators 110 expands while decoupling assembly 120 disengages and contracts while decoupling assembly 120 engages.

In addition to the dimensions of actuators 110 changing while decoupling assembly 120 engages and disengages, the length of spring 107 may also change. For example, the length of spring 107 gets longer as decoupling assembly 120 engages. Furthermore, when decoupling assembly 120 is disengaged, spring 107 may be nominally compressed depending on the cumulative mass of semiconductor die 103, package substrate 119, thermal interface material 109, integrated heat spreader 102, and other enabling and/or non-enabling components coupled to decoupling assembly 120. In addition to the cumulative mass enabling and non-enabling components, the spring constant of spring 107 also contributes to the compression.

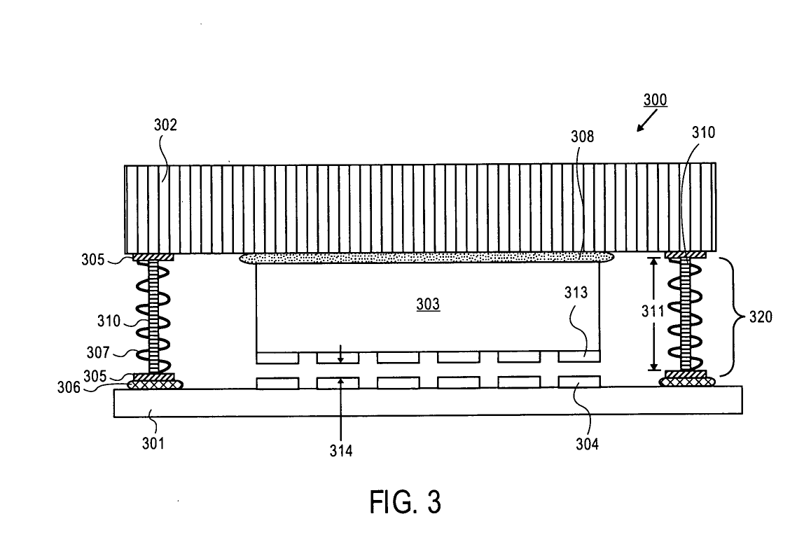

FIG. 3 shows two decoupling assemblies 320 disposed within a semiconductor package 300. Decoupling assemblies may include a clamping device 305, spring 307, and actuator 310 connected to a heat spreader 302 and a package substrate 301. Decoupling assemblies 320 can also reduce or prevent failure mechanisms caused by elevated temperatures, vibration, and/or shock. As shown, decoupling assembly 320 is engaged, which is defined as the state when semiconductor die 303 is de-coupled from a package substrate 301 and when actuators 310 are fully extended. For an embodiment when decoupling assembly 320 is engaged, actuator 310 has a length 311. For the embodiment, length 311 is the maximum length that actuator 310 can obtain. Additionally, the width of actuator 310 may be most narrow during the state when decoupling assembly 320 is engaged. Furthermore, the length of spring 307 may also change as decoupling 320 transitions from a disengaged state to an engaged state.

FIG. 3 shows a gap 314, which defines the separation distance between semiconductor die contacts 313 and package substrate contacts 304. Gap 314 can have a maximum distance of 1.0 mm and for an embodiment the distance of gap 314 is approximately 0.5 mm.

For the embodiment shown in FIG. 3, package substrate contacts 304 are landing pads that are employed in Land Grid Array (LGA) technology. For other embodiments, semiconductor die contacts 313 are pins and package substrates contacts 304 are pin openings that are employed in accordance with Pin Grid Array (PGA) technology.

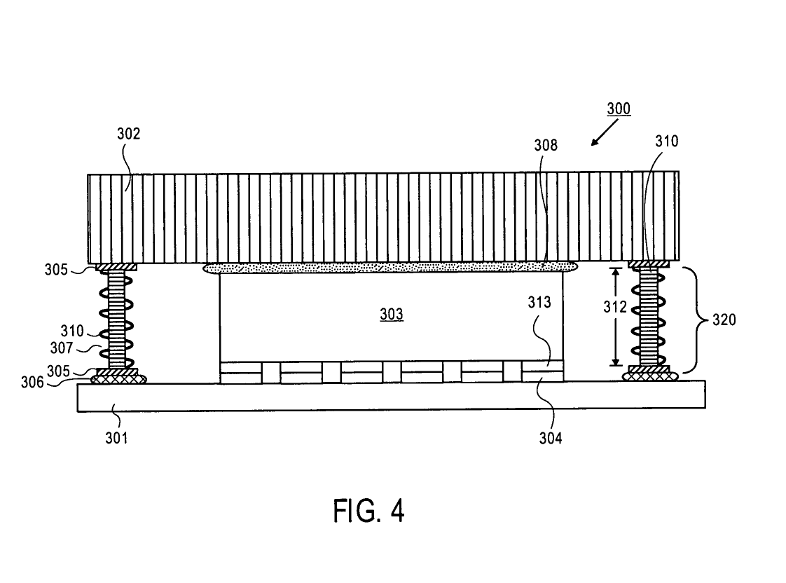

FIG. 4 shows a cross-section of a semiconductor package 300 that contains a disengaged decoupling assembly 320. For the embodiment shown, semiconductor die 303 couples to substrate 301 via contacts 313, 304 such that semiconductor die 303 may communicate with a circuit board or any other device coupled to substrate 301. For the embodiment shown, while decoupling assembly 320 is disengaged actuator 310 has a length 312. As stated previously, the length of actuator 310 changes as decoupling assembly 320 cycles between an engaged or disengaged state. Accordingly, length 312 is less than length 311 (of FIG. 3) as actuator 310 shortens when decoupling assembly 320 is disengaged and elongates when decoupling assembly 320 is engaged. The width of actuator 310 may also change as decoupling assembly 320 transitions from an engaged state to a disengaged state. For an embodiment, the width of actuator 310 contracts when decoupling assembly 320 is engaged and expands when decoupling assembly 320 is disengaged. Additionally, the length of spring 307 may change during decoupling assembly's 320 transition from an engaged state to a disengaged state.

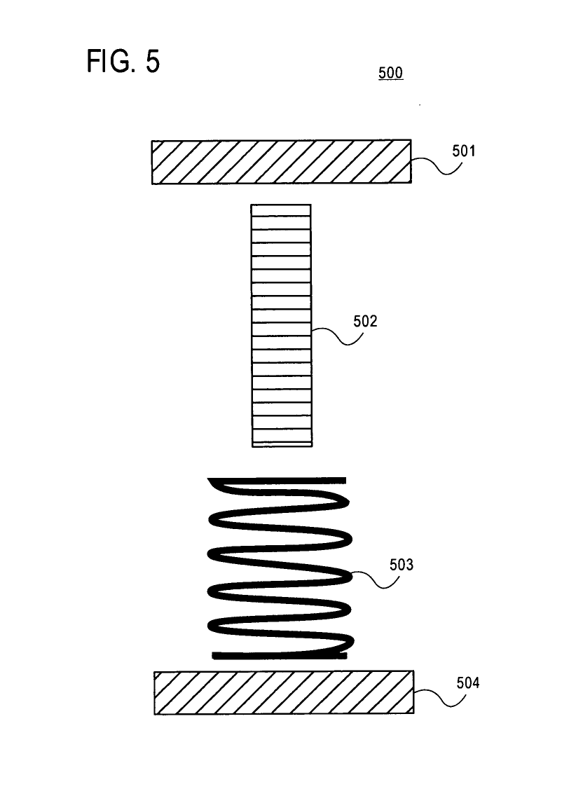

FIG. 5 shows an exploded view of components within a decoupling assembly 500. For the embodiment shown, decoupling assembly 500 includes an actuator 502, a spring 503, and clamping devices 501, 504. For an embodiment, clamping devices 501, 504 function within the decoupling assembly to contain actuator 502 and spring 503 in place. Spring 503 may provide a reverse loading when a decoupling assembly is engaged to decouple a semiconductor die from a package substrate or decouple a semiconductor package from a circuit board.

For an embodiment, actuator 502 facilitates coupling a semiconductor die to a package substrate or coupling a package substrate to a circuit board. In response to a stimulus, the length of actuator 502 shortens or elongates, which either couples or decouples a semiconductor die to a substrate or a semiconductor package to a circuit board. For various embodiments, actuator 502 responds to a thermal, shock, or a vibration stimulus. For embodiments when actuator 502 responds to a thermal stimulus at a temperature greater than or equal to approximately 125° C., actuator 502 elongates to a pre-programmed length and shape to provide a force and shortens once the temperature falls below approximately 120° C. Typically, the temperature of actuator 502 is within ±5° C. of a semiconductor package or a semiconductor die coupled to a decoupling assembly.

For other embodiments, actuator 502 responds to a shock or vibration stimulus such that actuator 502 shortens or elongates to a pre-determined level. Actuator 502 can improve processor performance during intermittent periods of shock and vibration while also improving the performance of a thermal interface material (TIM) by reducing TIM solder creep. For an embodiment, actuator 502 expands upon sensing a shock of 50 G and a level of vibration that exceeds 3.13 G. For embodiments, the level of shock experienced by actuator 502 closely matches the level of shock experienced by a semiconductor package or a semiconductor die coupled to a decoupling assembly.

For yet other embodiments, actuator 502 responds to a hybrid thermal/shock stimulus. For these embodiments, actuator 502 expands upon sensing a threshold temperature of 125° C. in addition to a threshold shock level of 50 G.

For embodiments, actuator 502 is a collection of shaped memory alloy wires that couples or decouples a semiconductor die to/from a package substrate or couples or decouples a semiconductor package from a circuit board. For these embodiments, actuator 502 configures to an austenite state when engaged and configures to a martensitic state when disengaged. Additionally, actuator 502 formed from a collection of shaped memory alloy wires can generate motion to a pre-programmed shape and apply a force when stimulated. For embodiments, each actuator 502 formed from a collection of shaped memory alloy wires can withstand a force of at least 70 N. Conventional semiconductor packages have a pre-load of approximately 300 N. Accordingly, five decoupling assemblies should be sufficient to support conventional semiconductor packages. For various embodiments, semiconductor packages have 4 to 10 decoupling assemblies disposed within. For other embodiments, 4 to 10 decoupling assemblies are disposed between a semiconductor package and a circuit board. The decoupling assemblies can be fixed on the perimeter, center, and/or interior areas of a package substrate and an integrated heat spreader.

Actuator 502 has a shape that complements the shape of spring 503 to accommodate fitting actuator 502 within spring 503. For an embodiment, both actuator 502 and spring 503 have a concentric shape. For the embodiment when actuator 502 has a concentric shape, the diameter of actuator 502 is approximately 40 microns. For other embodiments, actuator 502 and spring 503 may have non-concentric shapes, however, so long as actuator 502 fits within an interior of spring 503.

In the foregoing specification, the invention has been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. An apparatus, comprising:
a package substrate;
a semiconductor die over said package substrate;
a heat spreader over to said semiconductor die; and
a decoupling assembly connected to said package substrate and said heat spreader, wherein said decoupling assembly comprises a spring suspension and an actuator.

2. The apparatus of claim 1, wherein said semiconductor die is connected to said package substrate while said decoupling assembly is disengaged.

3. The apparatus of claim 1, wherein said semiconductor die is disconnected from said package substrate while said decoupling assembly is engaged.

4. The apparatus of claim 1, wherein said actuator responds to a stimulus selected from the group consisting of a thermal stimulus, a shock stimulus, and a vibration stimulus.

5. The apparatus of claim 1, wherein said actuator supports a minimum load of 70 Newtons.

6. The apparatus of claim 1, wherein said actuator lengthens when said decoupling assembly is disengaged and shortens when said decoupling assembly is engaged.

7. A computing system, comprising:
a circuit board;
a socket mounted to said circuit board;
a decoupling assembly mounted to said circuit board, wherein said de-coupling assembly comprises a spring and an actuator;
a semiconductor package over said decoupling assembly, wherein said semiconductor package is aligned above said socket to fit within said socket when said decoupling assembly is engaged.

8. The computing system of claim 7, wherein at least eight decoupling assemblies are disposed between said circuit board and said semiconductor package.

9. The computing system of claim 7, wherein said actuator comprises nickel and titanium.

10. The computing system of claim 7, wherein said actuator is in a martensite state when said decoupling assembly is disengaged and wherein said actuator is in a austensite state when said decoupling assembly is engaged.

11. An electronic system, comprising:
a circuit board;
a socket mounted to said circuit board;
a decoupling assembly coupled to said circuit board, wherein said de-coupling assembly comprises a spring suspension and a shaped memory alloy rod;
a heat spreader coupled to said decoupling assembly; and
a semiconductor package coupled to said heat spreader, wherein said semiconductor package is aligned above said socket to fit within said socket when said decoupling assembly is engaged.

12. The electronic system of claim 11, wherein said decoupling assembly further comprises a clamping device which is to mount to said circuit board and said heat spreader to couple said decoupling assembly to said circuit board and said heat spreader.

13. The electronic system of claim 11, wherein an accelerometer is coupled to said clamping device.

14. A semiconductor package, comprising:
a substrate;
a semiconductor die above said substrate;
a heat spreader coupled to said semiconductor die; and
a decoupling assembly coupled to said substrate and said heat spreader; wherein said decoupling assembly comprises a spring suspension and a shaped memory alloy rod.

15. The semiconductor package of claim 14 further comprising a processor retention mechanism, a processor clip, and a processor fan disposed above said semiconductor die.

16. The semiconductor package of claim 14, wherein said semiconductor die is a processor selected from the group consisting of a memory chip or a logic chip.

17. A method of forming an electronic system, comprising:
mounting a socket to a circuit board;
mounting a set of decoupling assemblies to said circuit board;
coupling a semiconductor package to said set of decoupling assemblies, wherein said semiconductor package is aligned to said socket.

18. The method of claim 17, wherein said socket is mounted to said circuit board by a technique selected from the group consisting of PGA and LGA.

19. The method of claim 17, wherein said set comprises four to ten decoupling assemblies.

20. The method of claim 17, wherein said semiconductor package is coupled to said set of decoupling assemblies by a thermal interface material.
